(19) United States
(12) Patent Application Publication
(10) Pub. No.: US 2013/0093300 A1
(43) Pub. Date: Apr. 18, 2013

(54) DECORATOR MOUNTING APPARATUS FOR PORTABLE TERMINAL

(71) Applicant: Samsung Electronics Co., Ltd., Gyeonggi-do (KR)

(72) Inventors: Seung-Chul BAEK, Seoul (KR); Kwang-Sub BONG, Seoul (KR); Jae-Young PARK, Seoul (KR)

(73) Assignee: Samsung Electronics Co., Ltd., Gyeonggi-do (KR)

(21) Appl. No.: 13/652,559

(22) Filed: Oct. 16, 2012

(30) Foreign Application Priority Data
Oct. 18, 2011 (KR) 10-2011-0106299

(51) Int. Cl. H05K 5/03

(52) U.S. Cl. 312/223.1

(57) ABSTRACT

A decorator mounting apparatus includes a housing; a display bracket coupled to the housing by a plurality of coupling parts; and a decorator mounted to the housing through coupling of the display bracket to the housing.

### CLAIM OF PRIORITY

This application claims the priority under 35 U.S.C. §119(a) of an application entitled “Decorator Mounting Apparatus for Portable Terminal” filed in the Korean Intellectual Property Office on Oct. 18, 2011 and assigned Serial No. 10-2011-0106299, the contents of which are hereby incorporated by reference.

### BACKGROUND OF THE INVENTION

1. Field of the Invention

The present invention relates to a portable terminal, and more particularly, the present invention relates to an earphone jack decorator employed in a portable terminal

2. Description of the Related Art

In general, a portable terminal refers to a portable information device such as a cellular phone, a notebook, a web hard, a web pad, a smart phone, and a tablet PC. A user connects an earphone jack to the portable terminal to privately listen to music or audio output of various videos or TV programs.

An earphone jack module standardized to output a voice is typically mounted to the portable terminal, and a connection terminal of the earphone jack module is exposed externally. Recently, the outer appearance of an externally exposed portion of the earphone jack module has been improved. To this end, a decorator of the earphone jack module is installed in the portable terminal which is manufactured by machining a thin film of a SUS material. The decorator has a separate mounting structure to be assembled in a housing of the portable terminal, and it is mounted to the housing to guide the insertion of an earphone (not shown), while providing an outer appearance of the portable terminal more appealing.

Referring to FIGS. 1 to 3, a conventional structure for mounting a decorator will be described hereinbelow.

FIG. 1 illustrates a portable terminal, e.g. a smart phone which includes a bar-shaped body 10. An entire shape of the body 10 is formed by coupling an upper housing 11 and a lower housing 12, and a parting line L1 can be seen when viewed from a side. A touch screen 15 is disposed on the upper housing 11 to be supported by a display bracket (not shown), which is disposed between the upper housing 11 and the lower housing 12 such that various parts and a display are mounted thereto.

A speaker 13, a touch screen 15, and a key 14 are sequentially disposed on an upper surface of the body 10, and an earphone jack module for connecting to an earphone jack (not shown) is located at the upper end surface of the body 10.

FIG. 2 illustrates a ring-shaped outer part where a decorator 16 is exposed to the outside.

Hereinafter, a conventional structure for mounting the earphone decorator 16 will be described with reference to FIG. 3.

As illustrated in FIG. 3, in the conventional decorator mounting structure, a separately prepared decorator 16 is inserted and fixed into a pair of hooks 17 and 18 formed on an inner surface 12a of the housing 12. That is, the decorator 16 can be firmly fixed by the hooks, which prevents the decorator 16 from being pushed into the housing 12 when the earphone is inserted.

However, the conventional decorator fixing apparatus requires a mechanical structure such as separate hooks 17 and 18. Further, since it is difficult to assemble the decorator 16 in the hooks 17 and 18, the assembling efficiency suffers. Furthermore, since there exists a parting line L1 in the portable terminal employing the conventional decorator mounting apparatus, an outer appearance of the portable terminal deteriorates. In addition, since the mechanical structure for mounting the decorator occupies an interior space of the housing, a space utility within the housing is not maximized.

Meanwhile, in a seamless housing where upper and lower housings are integrally formed, it is difficult to form hooks during a molding process. Thus, the decorator needs to be fixed using a tape. However, since the decorator cannot be firmly fixed using a tape, it is vulnerable to an external impact. The use of tape further causes the degradation of an external appearance of the portable terminal

Portable terminals are mass-produced, so if a decorator is assembled in a portable terminal with a trivial defect, an assembling efficiency of a portable terminal can also be lowered which in turn degrades a reliability of a product. Accordingly, there is a need for an improved way to mount a decorator firmly with an excellent assembling efficiency without degrading an outer appearance of a portable terminal

### SUMMARY OF THE INVENTION

Accordingly, an aspect of the present invention is to solve the above-mentioned problems occurring in the prior art, and to provide a decorator mounting apparatus by which a decorator can be mounted by using a coupling structure between a housing and a display bracket.

Another aspect of the present invention is to provide a decorator mounting apparatus by which a decorator can be mounted according to coupling of a display bracket to a housing without using a separate mechanical structure.

Still another aspect of the present invention is to provide a decorator mounting apparatus by which a decorator can be mounted according to coupling of one coupling part situated at a location corresponding to a location of the decorator in a coupling structure between a housing and a display bracket.

Yet another aspect of the present invention is to provide a decorator mounting apparatus by which a decorator can be mounted to a seamless housing.

A further aspect of the present invention is to provide a decorator mounting apparatus by which an outer appearance of a portable terminal can be improved using a single housing.

In accordance with an aspect of the present invention, there is provided a decorator mounting apparatus including: a housing; a display bracket coupled to the housing via a plurality of coupling parts; and a decorator mounted to the housing according to coupling of the display bracket.

In accordance with another aspect of the present invention, there is provided a decorator mounting apparatus for a portable terminal including: a housing; and a bracket coupled to the housing, wherein an earphone jack decorator disposed within the housing is mounted according to a coupling structure between the housing and the bracket.

### BRIEF DESCRIPTION OF THE DRAWINGS

The above and other aspects, features and advantages of the present invention will be more apparent from the following detailed description taken in conjunction with the accompanying drawings, in which:

FIG. 1 is a perspective view illustrating a portable terminal employing a conventional decorator mounting apparatus;

FIG. 2 is an enlarged view illustrating a decorator of FIG. 1;

FIG. 3 is a perspective view illustrating a conventional decorator mounting apparatus;

FIG. 4A is a front view illustrating a portable terminal employing a decorator mounting apparatus according to the present invention;

FIG. 4B is a side view of FIG. 4A;

FIG. 5 is a plan view of FIG. 4A;

FIG. 6 is a perspective view illustrating a state where a display bracket is coupled to a housing according to the present invention;

FIG. 7 is a perspective view illustrating a state where a decorator is disposed in a certain region in the housing according to the present invention;

FIG. 8 is a perspective view illustrating an outer appearance of the decorator disposed in the housing according to the present invention;

FIG. 9 is a bottom view illustrating a display bracket according to the present invention;

FIG. 10 is a sectional view illustrating the decorator mounting apparatus according to the present invention; and

FIG. 11 is a perspective view illustrating the decorator mounting apparatus according to the present invention, wherein the housing is removed.

### DETAILED DESCRIPTION

Hereinafter, a decorator mounting apparatus according to the present invention will be described with reference to the accompanying drawings. It should be noted that the same reference numerals denote the same or like elements in the drawings.

Briefly, the present invention provides a mounting apparatus employed in a decorator, e.g. an earphone jack decorator which enhances an external appearance of a portable terminal In particular, the teachings of the present invention can be applied to a seamless housing of a portable terminal, wherein a decorator is mounted by using a coupling structure between a housing and a display bracket as the housing is coupled to the display bracket. Thus, the present invention provides to a structure for mounting a decorator by using a coupling structure between a housing and a display bracket without using a separate decorator mounting apparatus.

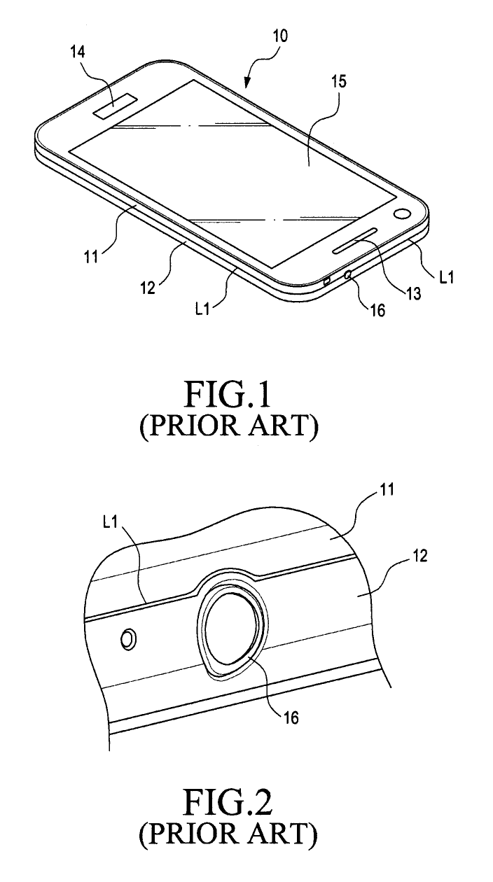

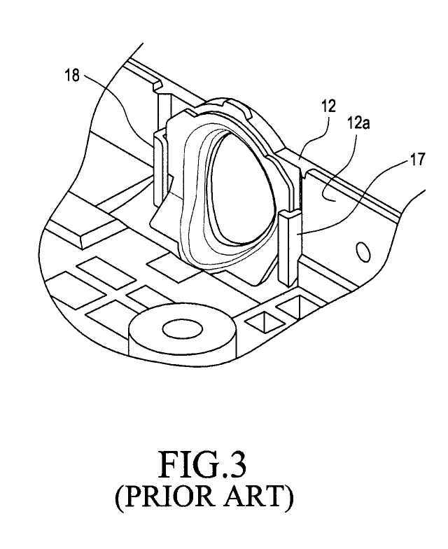

First, prior to a description of the present invention, the above-mentioned seamless housing will be described while being compared with the housing of a conventional portable terminal of FIGS. 1 and 2 in order to appreciate the teachings of the present invention.

As illustrated in FIGS. 1 and 2, the conventional portable terminal includes a bar-shaped body 10, and the body 10 is constructed by coupling two housings, i.e. an upper housing 11 and a lower housing 12. The upper housing 11 and the lower housing 12 are integrally coupled to each other to form a single bar-shaped body 10. Here, a display bracket (not shown) is mounted between the upper housing 11 and the lower housing 12, and various parts (not shown) and a display unit such as an LCD are disposed in the display bracket (not shown) so as to be protected. FIG. 2 clearly shows a parting line L1 dividing the body 10 into the upper housing 11 and the lower housing 12. The display unit (not shown) may include a display device such as an LCD or an AMOLED LCD.

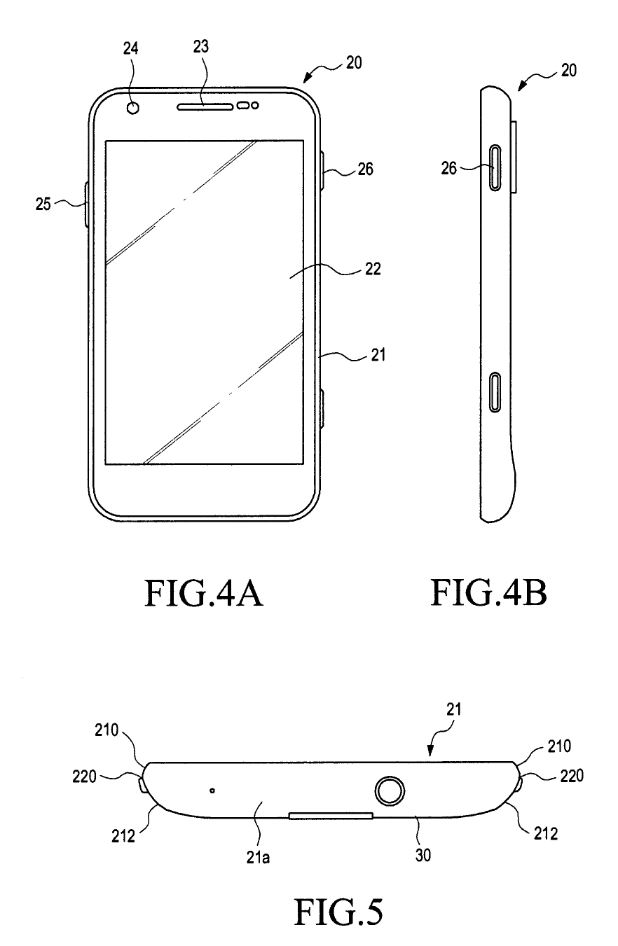

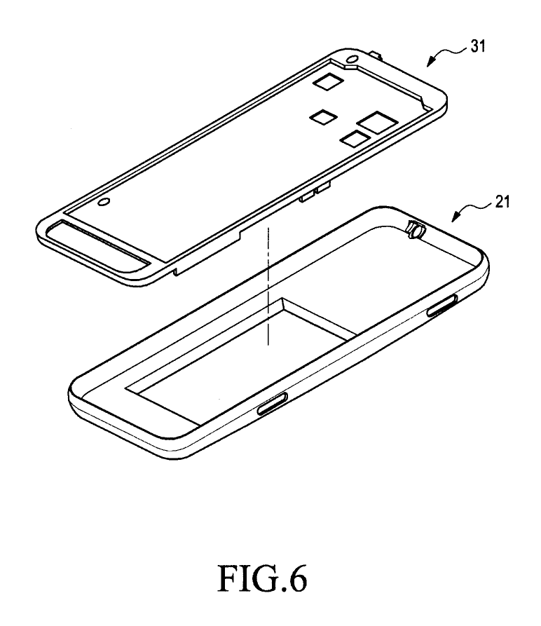

Meanwhile, as illustrated in FIGS. 4A and 4B, a body 20 of a portable terminal to which a decorator mounting apparatus according to the present invention is applied is achieved by coupling a single seamless housing (hereinafter, referred to as ‘housing’) and a display bracket (see FIG. 6). That is, while the conventional body includes three mechanical parts, i.e. an upper housing, a lower housing, and a display bracket, the present invention includes a single seamless housing 21 and a display bracket 31. Further, a touch screen 22, a speaker unit 23, and a camera lens 24 are disposed on an upper surface of the body 20. A volume key 25, an ON/OFF key 26, and a USB connection terminal are disposed on a side surface of the housing 21 of the body 20.

Referring to FIG. 5, the housing 21 includes an upper curved surface 210 and a lower curved surface 212 with respect to a portion of inflection 220 existing along a side surface 21a. The upper curved surface 210 and the lower curved surface 212 are opposed to each other with respect to the a portion of inflection. A decorator 30 to which an earphone jack (not shown) is connected is located on a side surface 21a.

Referring to FIG. 6, the body of the portable terminal includes the housing 21 and the display bracket 31 coupled to the housing 21. A display device, e.g. an LCD or an AMOLED display is mounted onto an upper surface of the display bracket 31 and various necessary parts are mounted onto a bottom surface thereof during manufacturing stage. Then, the display bracket 31 is coupled to the housing 21 and the below-described decorator is firmly fixed at a predetermined location of the housing 21. The display bracket 31 is coupled to the housing 21 via a plurality of coupling structures 320 provided around the outer circumference of the display bracket 31. One of the coupling structures refers to a boss 320, and one of a coupling unit mounts the decorator. That is, as the display bracket 31 is being inserted into the housing 21, the coupling structures 320 serves to is press-fit the housing 21 and the display bracket 31 together.

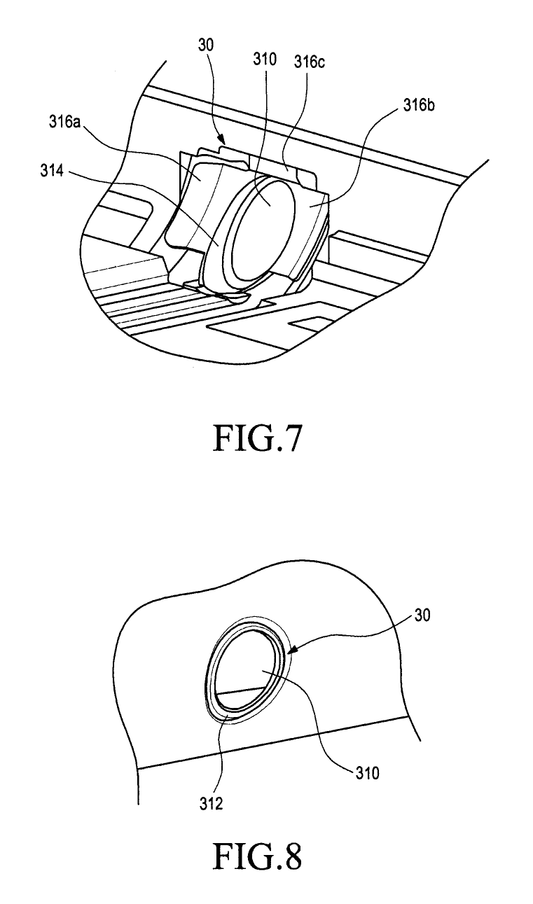

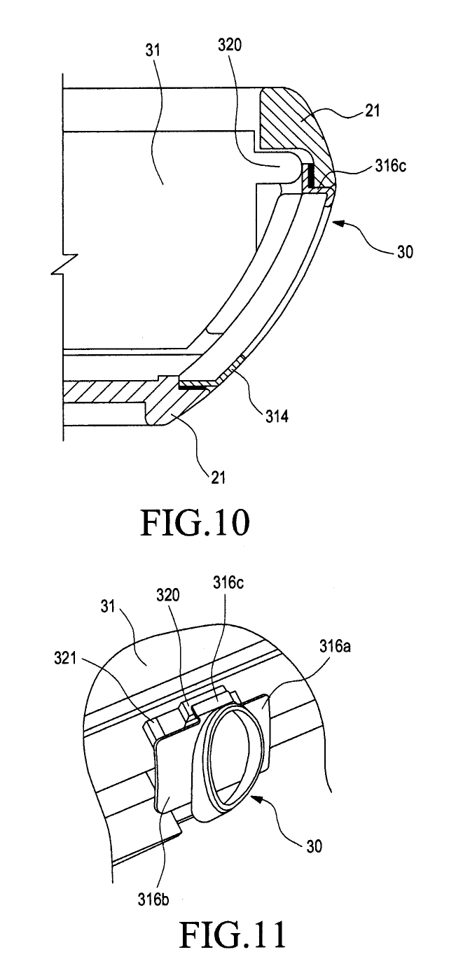

Referring to FIGS. 7 and 10, the decorator mounting apparatus according the embodiment of the present invention will be described hereinbelow.

As illustrated in FIGS. 7 and 8, the decorator 30 is disposed on an inner surface of the housing 21. FIGS. 7 and 8 illustrate a state of the decorator 30 before the display bracket 31 is mounted to the housing 21. That is, before the display bracket 31 is mounted to the housing 21, the decorator 30 is first attached to an inner surface of the housing 21. The decorator 30 is temporarily fixed by using a double-sided tape. The tape is a double-sided tape, and it is attached to a back surface of the catches 316a, b,c around an opening of the decorator. So, before the display bracket 31 is coupled to the housing 21, the tape is first attached to an inner surface of the housing 21 The tape-provides a location where the decorator 30 is fixed before the decorator 30 is mounted.

The decorator 30 includes an opening 310 through which the earphone jack (not shown) passes, a ring-shaped outer portion 312 and a peripheral portion surrounding the opening 310, and a plurality of catches 316. The ring-shaped outer portion 312 can be viewed from the outside when the decorator 30 is disposed on an inner surface of the housing 21. The peripheral portion 314 extends along an outer periphery of the outer portion 312 to support the outer portion 312. The catches 316 are formed at the peripheral portion 314 and serve to attach the decorator 30 on the inner surface of the housing 21 or catch the decorator 30. FIG. 7 illustrates three catching portions 316a, 316b, and 316c. Among the three catching portions 316a, 316b, and 316c, the left catching portion 316a and the right catching portion 316b attach the decorator 30 on the inner surface of the housing 21, and the upper catching portion 316c catches the decorator 30 on the inner surface of the housing 21. The catching structure of the upper catching portion 316c is illustrated in FIG. 10. The upper catching portion 316c is bent at the peripheral portion 314.

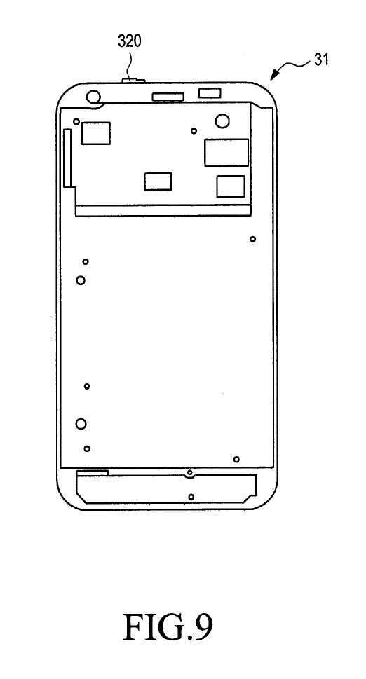

FIG. 9 is a bottom view illustrating the display bracket 31 according to the present invention. The display bracket 31 is substantially flat. A display device etc. are disposed on an upper surface of the display bracket 31 and various parts are disposed on a bottom surface of the display bracket 31. The display bracket 31 has a plurality of coupling parts on a side surface at a circumference of an upper end thereof, and only one coupling part 310 for mounting the decorator 30 is illustrated. The coupling part 320 is a boss. When the display bracket 31 is coupled to the housing 21, the boss 320 is structurally attached to the decorator 30 (see FIG. 10) to mount a certain region of the decorator 30. The boss 320 extends to the outside of the display bracket 31.

FIG. 10 illustrates a coupling state of the decorator 30. As shown, the display bracket 31 is press-fitted with and coupled to the housing 21 by using a plurality of coupling parts 320 (not shown). For illustrative purpose, only one coupling structure 320 is shown in FIG. 9. In the present invention, the boss integrally formed on the display bracket is formed corresponding to a location where the decorator is mounted.

At the same time, the decorator 30 is fixed to an internal region of the housing 21 through a coupling structure between the housing 21 and the display bracket 31. Then, one of the plurality of coupling parts is situated at a location corresponding to a location of the decorator 30 so that the decorator 30 is mounted by using the coupling part 320. The coupling part 320 is a boss. Hereinafter, among the plurality of coupling parts formed along a circumference of the display bracket 31, the coupling part 320 refers to one boss situated at a location corresponding to where the decorator 30 is mounted, and will be referred to as a boss hereinbelow.

When the display bracket 31 is press-fitted with and coupled to the housing 21, the boss 320 mounts the decorator 30 to a portion of the inner surface of the housing 21. In particular, the boss 320 is attached to the catching portion 316c of the decorator 30. The catching portion 316c of the decorator 30 is bent at the peripheral portion 314, and after being caught at a location of the inner surface of the housing 21 (temporarily fixed using a tape), is attached and mounted to the inner surface of the housing 21 by the boss 320. The double-sided tape is mounted on the back surface of catches of the decorator (i.e., an opposite side of the catches in FIG. 7).

As illustrated in FIGS. 10 and 11, if the display bracket 31 is coupled to the housing 21, the catching portions 316a, 316b, and 316c of the decorator are mounted by at least one boss 320 and 321 protruding from an outer surface of the display bracket 31. Accordingly, the decorator 30 is prevented from being inserted into the housing 21 by the at least one boss 320 and 321.

FIG. 11 illustrates a state where the housing 21 is removed. As illustrated in FIG. 11, if the display bracket 31 is coupled to the housing 21, the decorator 30 is attached and mounted to the bosses 320 and 321 of the display bracket 31. The bosses 320 and 321 formed on side surfaces of an upper end of the display bracket 31 are also attached to the catching portions 316a, 316b, and 316c to mount the decorator 30.

As discussed above, since the present invention provides a decorator mounted by a coupling structure between a display bracket and a housing in a portable terminal, it contributes to improvement of an assembling efficiency as mechanical components are used to hold the decorator as in the conventional art. Further, a decorator mounting structure can sufficiently endure an external impact as the decorator is not fixed using only a tape as in the conventional art. In addition, the utility of an interior space of a housing can be improved by mounting a decorator without using a separate mechanism.

While the invention has been shown and described with reference to a certain embodiment, it will be understood by those skilled in the art that various changes in form and details may be made therein without departing from the spirit and scope of the invention as defined by the appended claims.

What is claimed is:

1. A decorator mounting apparatus for a portable terminal, comprising:
a display bracket having a plurality of coupling parts on an outer circumference thereof;
a housing coupled to the display bracket via the plurality of coupling parts; and
a decorator mounted to the housing to be in contact with one of the plurality of coupling parts during the coupling of the display bracket and the housing.

2. The decorator mounting apparatus as claimed in claim 1, wherein the display bracket is received within the housing and coupled to each other via the plurality of coupling parts.

3. The decorator mounting apparatus as claimed in claim 1, wherein the one of the plurality of coupling parts is a boss integrally formed on the display bracket.

4. The decorator mounting apparatus as claimed in claim 1, wherein the one of the plurality of coupling parts prevents the decorator from being pushed into the housing.

5. The decorator mounting apparatus as claimed in claim 1, wherein the housing is a single seamless housing and comprises an upper curved surface and a lower curved surface with respect to a curved line at a side circumferential surface of the housing.

6. The decorator mounting apparatus as claimed in claim 1, wherein the one of the plurality of coupling parts extends from a circumference of an upper end of the display bracket outwardly.

7. The decorator mounting apparatus as claimed in claim 1, wherein a fixed location of the decorator is provided after the decorator is attached to an inner surface of the housing.

8. The decorator mounting apparatus as claimed in claim 1, wherein the decorator is an earphone jack decorator.

9. The decorator mounting apparatus as claimed in claim 1, wherein the decorator includes a ring-shaped outer portion, a peripheral portion extending along a circumference of the ring-shaped outer portion, and at least one catching part formed at the peripheral portion, attached to an inner surface of the housing, and bent at the peripheral portion.

10. The decorator mounting apparatus as claimed in claim 1, wherein the display bracket is substantially flat, and is press-fitted with the housing via the plurality of coupling parts.

11. A decorator mounting apparatus for a portable terminal comprising:
a housing; and
a bracket coupled to the housing,
wherein an earphone jack decorator disposed within the housing is mounted according to a coupling structure between the housing and the bracket.

12. The decorator mounting apparatus as claimed in claim 11, wherein the coupling structure includes a plurality of coupling parts formed at a circumference of the bracket, and the earphone jack decorator is coupled by one of the coupling parts situated at a location corresponding to a location where the earphone jack decorator is mounted on the housing.

13. The decorator mounting apparatus as claimed in claim 11, wherein the earphone jack decorator is temporarily mounted to the housing by using a double-sided tape.

14. The decorator mounting apparatus as claimed in claim 11, wherein the bracket is completed received within the housing while mounting the earphone jack decorator therebetween.

15. A portable terminal comprising:
a housing;
a display bracket coupled to the housing; and
an earphone jack decorator mounted to the housing through coupling of the display bracket to the housing.

16. The portable terminal as claimed in claim 15, the display bracket further includes a plurality of coupling parts formed on an outer circumference thereof

17. The portable terminal as claimed in claim 16, wherein the earphone jack decorator becomes in contact with one of the coupling parts during the coupling.

18. The portable terminal as claimed in claim 17, wherein the one of the plurality of coupling parts prevents the earphone jack decorator from being pushed into the housing.

19. The portable terminal as claimed in claim 15, wherein the earphone jack decorator is temporarily mounted to the housing by using a double-sided tape.

20. The portable terminal as claimed in claim 15, wherein the display bracket is completed received within the housing while mounting the earphone jack decorator therebetween.
